(19) United States
(12) Patent Application Publication
(10) Pub. No.: US 2004/0241461 A1
(43) Pub. Date: Dec. 2, 2004

(54) Preparation method for protecting the back surface of a wafer and back surface protected wafer

(76) Inventors: Thibaut Maurice, Grenoble (FR); Beryl Blondeau, La Tronche (FR)

Correspondence Address: WINSTON & STRAWN, PATENT DEPARTMENT, 1400 L STREET, N.W., WASHINGTON, DC, 20005-3502, US

(21) Appl. No.: 10/716,897

(22) Filed: Nov. 18, 2003

(30) Foreign Application Priority Data
May 26, 2003 (EP) 03291253.7

(51) Int. Cl. B05D 5/06; C23C 16/00

(52) U.S. Cl. 428/446; 428/689; 428/64.1; 427/162; 427/248.1

(57) ABSTRACT

The present invention relates to the preparation of a wafer that has front and back surfaces that are suitable for use in optical, electronic, opto electronic or micro mechanical devices. The wafer preparation method includes the improvement which comprises applying a cap layer proximate to at least a portion of the back surface of the wafer to facilitate handling of the wafer while protecting at least the back surface portion from damage. Advantageously, the cap layer can be applied proximate to the entire back surface of the wafer and along at least a portion of a side of the wafer that extends between the surfaces to fully protect the back surface of the wafer from damage during handling. In another embodiment, the method further comprises applying a top layer proximate to at least a portion of the front surface of the wafer.

### BACKGROUND

1. Field of the Invention

The invention relates to a wafer and a method of preparation of a wafer, in particular for semiconductor wafers designated to be used in the fabrication of devices for optical, electronic, opto electronic or micro mechanical applications.

### BACKGROUND OF THE INVENTION

Devices containing optical, electronic, opto electronic or micro mechanical features are usually fabricated on wafers made out of various materials like silicon, fused silica or gallium arsenide and can have different sizes and shapes. Usually, functional structures like transistors are manufactured on the front surface of the wafers. Due to the continuing decrease in size of these functional structures, the surface quality of the wafer, particularly on its front and the back surfaces, is becoming more and more important in order to keep processing yields on an economical level. Furthermore, new applications require use of both surfaces of a wafer. Such examples include micro mechanical (MEMS) devices or optical applications such as display devices, where the functional structures are built on one surface of a visually transparent wafer where the light leaves the device via the opposite surface of the wafer to the environment.

Moreover, wafer handling, which used to be performed by holding a wafer with an end effector on the back surface of the wafer, is becoming more and more critical, particularly with the arrival of 300 mm wafers. This leads to complicated and expensive wafer handling systems that preferably grip the wafers proximal to their edges.

Thus, there is a need for wafers and preparation methods therefor wafers that makes wafer handling less critical and enables one to obtain wafers with good final product quality. The present invention now satisfies this need.

### SUMMARY OF THE INVENTION

The present invention relates to the preparation of a wafer that has front and back surfaces that are suitable for use in optical, electronic, opto electronic or micro mechanical devices. The wafer preparation method includes the improvement which comprises applying a cap layer proximate to at least a portion of the back surface of the wafer to facilitate handling of the wafer while protecting at least the back surface portion from damage. Advantageously, the cap layer is applied proximate to the entire back surface of the wafer and optionally along at least a portion of a side of the wafer that extends between the surfaces to fully protect the back surface of the wafer from damage during handling.

In another embodiment, the method further comprises applying a top layer proximate to at least a portion of the front surface of the wafer, preferably to the entire front surface of the wafer.

The method preferably included creating a first functional structure on the front surface of the wafer, wherein the cap layer can be applied before the first functional structure is created. If desired, a second functional structure can be created on the front surface of the wafer, wherein the cap layer is applied after the first functional structure is created, but before the second functional structure is created.

The cap layer may be applied as first and second sublayers. The wafer that includes the sublayers is generally advanced to a location where the functional structure is created on the front surface of the wafer, and then at least one of the sublayers is removed before or after the functional structure is created. The sublayer can be removed by at least one of dry etching, wet etching or polishing. An etch stop layer can be applied as the sublayer that is positioned closer to the wafer so that it can protect the wafer during a chemical polishing step.

The cap layer can be applied by various methods, including chemical vapor deposition (CVD), physical vapor deposition (PVD), plasma enhanced CVD, low pressure CVD, sputtering and evaporation.

The invention also relates to the wafer provided by the preparation method, as well as to a display device comprising one of these wafers and a computer system comprising one of these display devices.

Other aspects, objects and advantages of the invention will be better understood on reading the following detailed description of an implementation explained below.

### BRIEF DESCRIPTION OF THE DRAWINGS

In the following preferred embodiments of the inventive wafer and the inventive preparation method are described with respect to the Figures, in which:

FIG. 1 shows a perspective view of a wafer according to a first embodiment of the invention showing a cross-section perpendicular to the front surface of the wafer;

FIG. 2 shows a perspective view of a wafer according to a second embodiment of the invention showing a cross-section perpendicular to the wafer front surface of a silicon on insulator (SOI) wafer or silicon on quartz (SOQ) wafer;

FIG. 3 shows a perspective view of a wafer according to a third embodiment of the invention showing a cross-section perpendicular to the front surface of a SOI or SOQ wafer; and

FIGS. 4(a)-4(j) show a method of preparing a wafer in accordance with the invention.

### DETAILED DESCRIPTION OF THE PREFERRED EMBODIMENTS

The cap layer protects the wafer against damage that could occur on the back surface of the wafer, such as mechanical or chemical damage. The cap layer sticks sufficiently well to the surface of the wafer and its physical and chemical characteristics are such that the integrity of the back surface is ensured.

With the surface quality of the cap layer being by far not so important than the surface quality of the now underneath lying wafer back surface, the wafer handling process becomes less critical and some state of the art wafer handling mechanisms can be applied with less risk of damaging the wafer. For devices where the back surface plays a role, such as a display device where light leaves the device via the back surface of a transparent wafer, this process is advantageous because less scratches are formed during the processing on the wafer back surface, which becomes the viewable portion of the display. Thus, enhanced product quality and higher production yield can be obtained.

The top layer, which can be one layer but can also be composed of several sub layers, is provided proximal to, (i.e., on or in), the front surface of the wafer. Such wafers include, for example, silicon on insulator (SOI), silicon on quartz (SOQ) and the like. To make these wafers a number of additional process steps are necessary, each one presenting a certain risk of damaging or contaminating the back surface of the wafer. Therefore, the cap layer is fabricated proximate to the back surface before the additional top layer is provided on or in the front surface of the wafer. This ensures the integrity of the wafer back surface against mechanical or chemical damage.

An etch stop layer is applied as a sublayer of the cap layer when chemical mechanical polishing is used. Where the material removal process is not sufficiently element-selective, due to the material characteristics of the protective layer and/or the wafer, such that the removal process is a source of unwanted wafer back surface damage, it is advantageous to apply the additional etch stop layer, which is sandwiched between the protective layer and the wafer. The physical and chemical properties of this layer are preferably chosen such as to allow the removal of the protective cap layer up to the etch stop layer.

The cap layer can include at least two sub layers. Such layers can include, for example, an etch stop layer. The sub layer can have a minimum thickness of about 20 nm, preferably between about 50-1000 nm. In the case that the cap layer includes more than one sub layer, other sub layers can also have thicknesses according to the above mentioned minimum of approximately 20 nm and a particularly suitable range of 50-1000 nm. At least one sub layer of the cap layer includes a material from the group consisting of SiO₂, Si₃N₄ and diamond like carbon (DLC). These layers can be easily applied in good quality and have sufficient protective effect.

In accordance with still another aspect of the invention, a display device is provided including a wafer and a cap layer proximate to a back surface of the wafer, where the cap layer is configured to protect the wafer from scratches during handling. Such a display device can be incorporated into a computer system. Sub layers can have various functions. For example, in a display device, one or more sublayers might fulfil the role of an antireflective coating. However at least one of the sub layers still plays the role of a protective layer against mechanical or chemical damage. This protective layer is not necessarily the outermost sub layer.

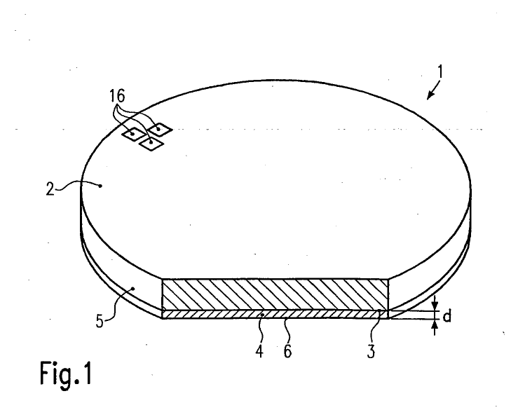

In accordance with the invention and as depicted in FIG. 1, a wafer 1 is provided. Wafer 1 can be used in the fabrication of devices for optical, electronic, opto electronic or micro mechanical applications. Wafer 1 has a front surface 2 and a back surface 3. On the back surface 3 of wafer 1 a cap layer 4 is applied, providing protection against back surface damage. Usually the wafer 1 has a disk-like shape, but also rectangular or square formats are possible. Disk-like wafers 1 usually have diameters of up to 300 mm, but in the future even bigger diameters are foreseen. In most applications the front surface 2 is polished, however in further applications both surfaces of the wafer 1 may be polished. Typical wafer materials include silicon, gallium arsenide (GaAs), germanium (Ge), indium phosphide (InP), gallium nitride (GaN), fused silica or quartz, with the list not being exclusive.

FIG. 1 shows cap layer 4 covering the entire back surface 3 of the wafer 1. Furthermore it is also possible to extend the cap layer onto the wafer side walls 5. Typical suitable materials for the cap layer 4 include, for example, silicon dioxide, silicon nitride or diamond-like carbon. The minimum thickness d of the cap layer 4 is approximately 20 nm, but preferably the thickness should be in a range of 50-1000 nm. Depending on the further use of the wafer 1, the surface 6 of the cap layer 4 can either be polished or not.

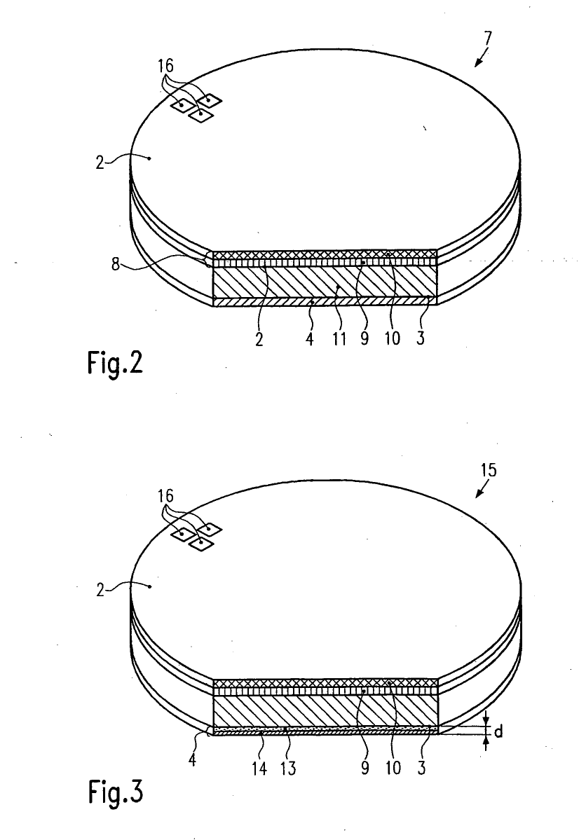

In accordance with another aspect of the invention, FIG. 2 shows a SOI or SOQ wafer 7. Compared to the wafer 1 shown in FIG. 1 this kind of wafer has a top layer structure 8 proximate to the wafer front surface 2. In an SOI wafer 7 this top layer 8 is made out of at least two top sublayers 9 and 10. Top sublayer 9 which is on top of the wafer front surface 2 is preferably an insulator such as silicon dioxide. The second top sublayer 10 is preferably a semiconductor material such as silicon. The wafer material 11 of an SOI wafer can be silicon and for a so-called SOQ wafer the wafer material 11 can be fused silica. Similar to wafer 1 of FIG. 1, the back surface 3 of wafer 7 is covered by cap layer 4, which fulfils the role of the protective layer. All above-mentioned characteristics of the cap layer 4 are also valid for this kind of wafer 7.

In accordance with another aspect of the invention, FIG. 3 shows wafer 15 having a cap layer 4 which is formed out of two sub layers 13, 14. In this example the first sub layer 13, which is applied directly on the back surface 3 of the wafer 15, is an etch stop layer. The second sub layer 14 represents the layer providing the protection. Like for wafer 7, shown in FIG. 2, the wafer front surface 2 is covered by a top layer 8 made out of two top sub layers 9 and 10, having the same material characteristics as the two top sub layers described previously.

In this example the outermost sub layer 14 of the cap layer 4 is silicon dioxide which provides the protection against mechanical and chemical damage, and inner sub layer 13 is made out of silicon nitride. Moreover, other material combinations are also possible and known to those of skill in the art.

In accordance with a further aspect of the invention, putting more than one sub layer on back surface 3 of wafer 15 allows selective etching. For example, different methods are available to eliminate the different sub layers including, for example, dry or wet etching and polishing or touch polishing. The final goal of the choice of the sub layer materials is that after removing the sub layers by these said different methods, back surface 3 of wafer 15 presents no defects. Thus, in the multiple sub layer structure, the material of the sub layer 14 can be chosen such that it is a well functioning protective layer without being concerned that it can be removed without damaging the back surface 3 of the wafer 15. The material of sub layer 13 can be chosen such as to be directly on the surface of the back surface 3 of wafer 15 and to have characteristics such that removal of sub layer 13 is possible without damaging back surface 3. Moreover, the cap layer of the first and second embodiments can also have a multilayer structure as with the third embodiment.

The three exemplary embodiments described above can be provided with functional structures 16 on at least front surface 2 of wafer 1, 17, or 15. These functional structures 16 can be, for example: transistors, electrodes, insulators, coatings, mirrors or micro mechanical structures. Structures 16 need not be provided proximate to the whole surface 2 of the wafer 1, 7 or 15.

In accordance with a further aspect of the invention, cap layer 4 on back surface 3 of wafers 1, 7, 15 can be configured to only partially cover back surface 3. For example, cap layer 4 can be configured to only cover portions of wafers 1, 7, 15 at places that are later on touched by the wafer handling system, or only those areas of the wafer where the back surface is going to be important for the final product.

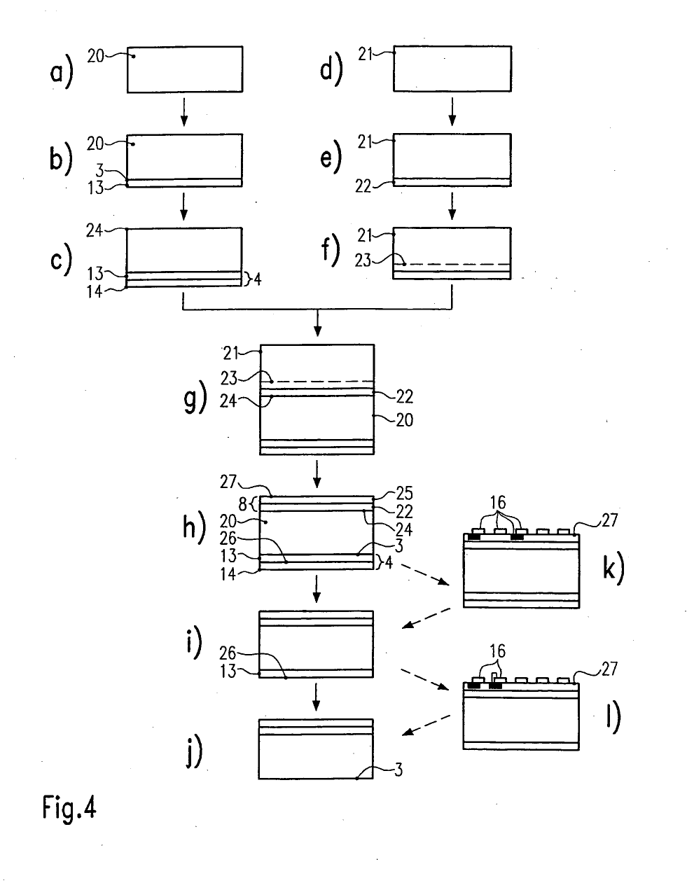

In accordance with another aspect of the invention and as depicted in FIGS. 4(a)-4(j) the invention provides a method of producing a wafer. This method can be used to produced an SOI or SOQ-type wafer 7 and 15 such as those depicted in FIGS. 1 and 2, wherein the back surface 3 of the wafer is covered by the cap layer 4, although the method of the invention is not so limited. While a number of processes are known in the art to obtain SOI or SOQ-type wafers, as depicted herein, the well known SMARTCUT® process is shown, as modified by the invention disclosed herein. Specifically, of interest are the process steps providing the cap layer 4 on the back surface 3 of the wafer.

In further accordance with the invention and as depicted in FIG. 4a a wafer 20, such as the wafer depicted in FIG. 1 is provided. In the SMARTCUT® process this wafer is called base wafer 20.

Next, in further accordance with the method of the invention and as depicted in FIG. 4b, a first sub layer 13 is deposited on the back surface 3 of the base wafer 20. This first sub layer can be made out of silicon (SiO₂), as in the earlier disclosed embodiments. However, other types of layers can also be deposited. In principal, the sub layer 13 can be deposited by any suitable deposition method. In particular, suitable methods include plasma enhanced chemical vapor deposition (PECVD), low pressure chemical vapor deposition (LPCVD) and/or sputtering. PECVD is, for example, performed in a reactor at temperatures up to 400° C. and at pressures of about 2.5 Torr. The deposited film is a product of a chemical reaction between SiH₄ and N₂O. The plasma discharge is sustained by radio frequency (“RF”) waves at a power level of about 200W to increase the available energy for the reaction. A possible frequency for the RF equipment is 13.56 MHz. The film is usually deposited in a few seconds. The layer is preferably fabricated with a minimum thickness of approximately 20 nm, but in particular with a thickness in a range of approximately 50-1000 nm. The LPCVD is applied on two surfaces and the PECVD is applied on one surface of the wafer.

Following the first sub layer deposition step, a second sub layer 14 is deposited onto the first sub layer 13, which is shown in FIG. 4c. Second sub layer 14 can be a silicon nitride layer (Si₃N₄), but other materials are also suitable. Second layer 14 can be deposited by any suitable deposition method, such as PECVD and LPCVD. For PECVD the process parameters for the SiO₂ layer include a reactor temperature of up to about 400° C., pressure of about 5 Torr, RF power supplied of about 625W and reactive gases such as SiH₄, N₂ and NH₃ can be used. Similar to the Si₃N₄ layer, the SiO₂ layer is deposited in a few seconds. Again, second layer 14 is preferably fabricated with a minimum thickness of approximately 20 nm, but preferably with a thickness in a range of approximately 50-1000 nm. As can be seen in step 4c, second sub layer 14 is covering the whole surface of the first sub layer 13, which leads to a sandwich-like structure.

Next, in further accordance with the method of the invention and as depicted in FIG. 4d, a second wafer is provided which in the SMARTCUT® process is called top wafer 21. Such a wafer 21 also has properties similar to those described herein. In a process step top wafer 21 gets oxidized, the result of which is depicted in FIG. 4e. Due to the oxidation process at least on one surface of the wafer 21, an oxide layer 22 is formed. In a subsequent process step depicted in FIG. 4f, hydrogen 23 gets implanted into the top wafer 21. The process steps depicted in FIGS. 4e and 4f can be performed in parallel to the process steps depicted in FIGS. 4b and 4c.

In further accordance with the method of the invention and as depicted in FIG. 4g, the top wafer 21 and the base wafer 20 are bonded together. During the bonding process oxide layer 22 of top wafer 21 is brought into contact with front surface of the base wafer 24.

Next, in further accordance with the invention, the part of top wafer 21 above the hydrogen line 23 is detached from the remaining wafers, according to the SMARTCUT® process. The result of this process step is depicted in FIG. 4h. The wafer now has a cap layer 4 on the base wafer back surface 3 and a top layer 8 on front surface 24 of former base wafer 20. As depicted in FIG. 4(h), top layer 8 is made out of two top sub layers 22, 25 wherein the first top sub layer 22 represents the oxide layer and the second top sub layer 25 represents the semiconductor layer. The cap layer 4 has two sub layers 13, 14, and reference 26 depicts the interface between the two sub layers.

In a subsequent, optional, process step the first sub layer 14 is removed from the cap layer structure 4, the result of which is depicted in FIG. 4i. The removal method is chosen to be such that the removal process stops at the interface 26 to the second sub layer 13 of the cap layer 4. This is achieved by element selective removal methods like, for example wet etch, dry etch or chemical mechanical polishing. In accordance with this aspect of the invention, where the to be removed layer is preferably made out of silicon dioxide, a suitable removal method is wet etch with hydrofluoric acid (HF) or dry etch like reactive ion plasma etching (RIE), direct current (DC) or radio frequency (RF) sputtering or inductively coupled plasma (ICP), typically using CF₄, C₂F₆ or CHF₃, and also CMP using oxide pads. These removal methods have a high removal rate, which is the amount of material removed per time unit, for SiO₂ and have a slower removal rate for the subsequent layer, which is preferably Si₃N₄. Thus the removal process can be easily controlled to stop at interface 26.

In accordance with a further aspect of the invention, FIG. 4j depicts an alternative process step wherein the first sub layer 13 of cap layer 4 is removed. In accordance with this aspect of the invention, sub layer 13 is made out of Si₃N₄ for example. A suitable removal method is wet etch with concentrated hot orthophosphoric acid (H₃PO₄). The result of this process step can be seen as depicted in FIG. 4j, where the SOI or SOQ wafer is shown, of which the back surface 3 has been protected during the whole SOI or SOQ fabrication process.

Additionally or alternatively, in further accordance with the invention, FIGS. 4k and 41 depict optional process steps that can be performed between the steps depicted in FIGS. 4h and 4i and/or between the steps depicted in FIGS. 4i and 4j wherein functional structures 16 are manufactured proximate to the front surface 27 of the SOI or SOQ wafer. These functional structures 16 can be, for example: transistors, electrodes, insulators, coatings, mirrors and/or micro mechanical structures. Functional layers 16 can of course also be manufactured after the process step depicted in FIG. 4i.

Moreover, it is to be understood that the cap layers disclosed herein are all artificial layers applied to the wafers.

In further accordance with the invention, the above described process could, for example, be used to manufacture a display device, such as flat panel displays used in personal computers, high definition televisions, cell phones, PDAs and the like. In such a device, use is made of a SOQ wafer 15, where the front surface 27 contains the necessary electronic functional structures 16 such as transistors, electrodes, signal lines and where light created in those structures travels through the wafer 15 to leave the wafer at the back surface 3 towards the environment. As back surface 3 was protected during at least a part of the production process, the presence of scratches, that would deviate or scatter the light and therefore lower the display quality, is greatly reduced. Other examples where the inventive method or the inventive wafer could be used include sensors, wherein light enters the device via quartz or light emitting diodes.

It will be apparent to those skilled in the art that various modifications and variations can be made in the present invention without departing from the spirit or scope of the invention. Thus, it is intended that the present invention include all such modifications and variations within the scope of the appended claims and their equivalents.

What is claimed is:

1. In a method of preparing a wafer that has front and back surfaces that are suitable for use in optical, electronic, opto electronic or micro mechanical devices, the improvement which comprises applying a cap layer proximate to at least a portion of the back surface of the wafer to facilitate handling of the wafer while protecting at least the back surface portion from damage.

2. The invention of claim 1, wherein the cap layer is applied proximate to the entire back surface of the wafer and optionally along at least a portion of a side of the wafer that extends between the surfaces to fully protect the back surface of the wafer from damage during handling.

3. The invention of claim 1, which further comprises applying a top layer proximate to at least a portion of the front surface of the wafer.

4. The invention of claim 3, wherein the top layer is applied proximate to the entire front surface of the wafer and optionally along at least a portion of a side of the wafer.

5. The invention of claim 3, wherein the cap layer is applied to the back surface of the wafer before the top layer is applied the front surface of the wafer.

6. The invention of claim 1, wherein the cap layer is applied by at least one of the methods consisting of chemical vapor deposition (CVD), physical vapor deposition, plasma enhanced CVD, low pressure CVD, sputtering and evaporation.

7. The invention of claim 1, which further comprises creating a first functional structure on the front surface of the wafer, wherein the cap layer is applied before the first functional structure is created.

8. The invention of claim 7, which further comprises a creating a second functional structure on the front surface of the wafer, wherein the cap layer is applied after the first functional structure is created, but before the second functional structure is created.

9. The invention of claim 7, wherein the cap layer is applied as first and second sublayers.

10. The invention of claim 9, which further comprises advancing the wafer that includes the sublayers to a location where the functional structure is created on the front surface of the wafer, and then removing at least one of the sublayers before the functional structure is created.

11. The invention of claim 9, which further comprises advancing the wafer that includes the sublayers to a location where the functional structure is created on the front surface of the wafer, and then removing at least one of the sublayers after the functional structure is created.

12. The invention of claim 11 wherein the sublayer is removed by at least one of dry etching, wet etching or polishing.

13. The invention of claim 11, wherein the sub layer is removed by chemical mechanical polishing.

14. The invention of at claim 9, which further comprises applying an etch stop layer as the sublayer that is positioned closer to the wafer.

15. A wafer provided by the invention of claim 1.

16. A wafer that has front and back surfaces that are suitable for use in optical, electronic, opto electronic or micro mechanical devices, and a cap layer proximate to at least a portion of the back surface of the wafer to facilitate handling of the wafer while protecting at least the back surface portion from damage.

17. The wafer of claim 16, wherein the cap layer includes at least two sublayers.

18. The wafer of claim 17, wherein the sublayer that is positioned closer to the wafer comprises an etch stop layer.

19. The wafer of claim 16, wherein the cap layer includes a sublayer having a minimum thickness of about 20 nm.

20. The wafer of claim 19, wherein the sub layer has a thickness of between about 50-1000 nm.

21. The wafer of claim 16, wherein the cap layer includes a material from the group consisting of SiO₂, Si₃N₄ and diamond like carbon.

22. A display device comprising the wafer of claim 15.

23. A display device comprising the wafer of claim 16.

24. A computer system comprising the display device of claim 22.

25. A computer system comprising the display device of claim 23.
